(19) United States
(12) Patent Application Publication
(10) Pub. No.: US 2002/0189091 A1
(43) Pub. Date: Dec. 19, 2002

(54) Method of making printed circuit board

(75) Inventors: Yi Chuan Ding, Kaohsiung (TW); Kun Ching Chen, Tainan (TW); In De Ou, Kaohsiung (TW)

Correspondence Address: Benjamin J. Hauptman, LOWE HAUPTMAN GILMAN & BERNER, LLP, Suite 310, 1700 Diagonal Road, Alexandria, VA, 22314, US

(73) Assignee: ADVANCED SEMICONDUCTOR ENGINEERING, INC.

(21) Appl. No.: 09/883,194

(22) Filed: Jun. 19, 2001

(51) Int. Cl. H05K 3/36

(52) U.S. Cl. 29/840; 29/830

(57) ABSTRACT

A method of making a printed circuit board mainly comprises mechanically and electrically attaching a first substrate to a second substrate having an opening defined therein via solder balls, column-like solder bumps or anisotropic conductive adhesive film (ACF) thereby obtaining a multilayer circuit board with a cavity or a three-dimensional structure. The upper surface of the first substrate is provided with a first set of contacts adapted for electrical coupling to a semiconductor chip and a second set of contacts. For making electrical connection to an outside printed circuit board, the lower surface of the first substrate is provided with a third set of contacts which are designed to electrically interconnect to the first set of contacts and the second set of contacts. The second substrate is provided with a set of interconnection pads formed on a lower surface thereof.

### BACKGROUND OF THE INVENTION

1. Field of the Invention

This invention relates to a method of making a printed circuit board having a multilayer structure.

2. Description of the Related Art

Usually, printed circuit boards are formed from a layer of conductive material (commonly, copper or copper plated with solder or gold) carried on a core layer of insulating material (commonly glass-fiber-reinforced epoxy resin). A printed circuit board having two conductive surfaces positioned on opposite sides of a single insulating layer is known as a “double-sided circuit board.” To accommodate even more circuits on a single board, several copper layers are sandwiched between layers of insulating material to produce a multilayer circuit board.

The multilayer printed circuit boards can be fabricated by the following processing steps. Initially, at least one inner core, of the FR4 material, is provided and copper foil is adhered to opposing sides thereof. Thereafter, the copper foil is etched to form desired electrical circuit patterns. Alternating layers of prepreg material and electrical circuit patterns (made from copper foil layers) are provided along both of the opposed sides of the inner core or cores having the electrical circuit patterns thereon, to form a stack, with at least one prepreg layer provided between adjacent layers of electrical circuit patterns. Copper foil forms the outer layers of these multilayer printed circuit boards, and these outer layer copper foils are etched to form desired electrical circuit patterns and/or connections for electrical components such as integrated circuit chips. The stack is subjected to heat and pressure to cure resin material of the prepregs so as to form a laminate of the stack. The number of layers of prepreg material, and the total number of layers of copper foil (including layers of copper foil on the inner core, with each copper foil layer having been etched to form a desired electrical circuit pattern), can be as desired, but generally four or more layers of copper foil are utilized. Usually, electrical connection to the inner layers of electrical circuit patterns is achieved by drilling vias and through-holes in the formed laminate to the inner layers and providing conductive material in the via-holes.

However, so far as the multilayer printed circuit is concerned, a major factor to limit pattern density is through hole and its pad. Pad diameter is generally larger than drill diameter by 0.2 mm or so to compensate for the drill misregistration laminate expansion/shrinkage and photo tool expansion/shrinkage. For a through-hole pad of inner-layers in a multilayer structure, it is more difficult to control the positional relationship between drill hole and pad because inner-layer pads are not visible from the outside, so the pad diameter needs to be 0.5 to 0.8 mm larger than the drill diameter. Therefore, it is quite difficult to have a high pattern density in the multilayer printed circuit mentioned above.

### SUMMARY OF THE INVENTION

Therefore, it is a primary object of the present invention to provide a method of making a printed circuit board which overcomes, or at least reduces the above-mentioned problems of the prior art.

The method of making a printed circuit board according to the present invention mainly comprises mechanically and electrically attaching a first substrate to a second substrate having an opening defined therein via solder balls, column-like solder bumps or anisotropic conductive adhesive film (ACF) thereby obtaining a multilayer circuit board with a cavity or a three-dimensional structure. The upper surface of the first substrate is provided with a first set of contacts adapted for electrical coupling to a semiconductor chip and a second set of contacts. For making electrical connection to an outside printed circuit board, the lower surface of the first substrate is provided with a third set of contacts which are designed to electrically interconnect to the first set of contacts and the second set of contacts. The second substrate is provided with a set of interconnection pads formed on a lower surface thereof.

It is noted that the first substrate and the second substrate are not laminated together through the conventional prepreg layer by thermocompression bonding. Further, the first substrate and the second substrate are manufactured and tested separately before mounting together. Since the first substrate is mechanically and electrically interconnected to the second substrate via solder balls, column-like solder bumps or ACF, electrical connection between the first and the second substrates is not achieved by conventional through-holes. Therefore, pattern density of the first substrate and the second substrate are not limited by the through-holes, and more circuits can be designed in the substrate thereby overcoming, or at least reducing the above-mentioned problems of the prior art.

### BRIEF DESCRIPTION OF THE DRAWINGS

Other objects, advantages, and novel features of the invention will become more apparent from the following detailed description when taken in conjunction with the accompanying drawings.

FIG. 1 is a cross sectional view of a printed circuit board according to a first preferred embodiment of the present invention;

FIG. 2 is a cross sectional view of a printed circuit board according to a second preferred embodiment of the present invention;

FIG. 3 is a cross sectional view of a printed circuit board according to a third preferred embodiment of the present invention;

FIG. 4 is a cross sectional view of a semiconductor chip package using the printed circuit board shown in FIG. 1 of the present invention; and

FIG. 5 is a cross sectional view of a multichip module using the printed circuit board shown in FIG. 1 of the present invention.

### DETAILED DESCRIPTION OF THE PREFERRED EMBODIMENT

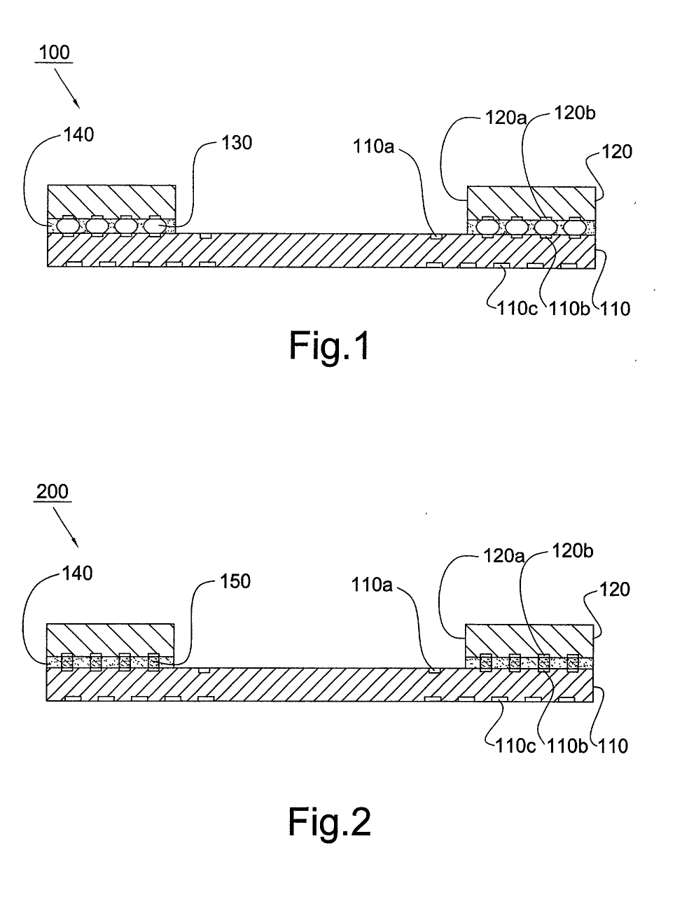

Referring to FIG. 1, the method of making a multilayer printed circuit board 100 according to a first preferred embodiment of the present invention is set forth below.

First, two substrates 110, 120 are prepared. The upper surface of the substrate 110 is provided with a first set of contacts 110a adapted for electrical coupling to a semiconductor chip and a second set of contacts 110b. For making electrical connection to an outside printed circuit board, the lower surface of the substrate 110 is provided with a third set of contacts 110c which are designed to electrically interconnect to the first set of contacts 110a and the second set of contacts 110b. The substrate 120 has an opening 120a defined therein and is provided with a set of interconnection pads 120b formed on a lower surface thereof. Though only two layers of conductor circuits of the substrate 110 are shown in this preferred embodiment, a substrate for use with the invention can include any number of layers of conductor circuits if desired. Preferably, the substrates 110, 120 are formed from a core layer made of fiberglass reinforced BT (bismaleimide-triazine) resin or FR-4 fiberglass reinforced epoxy resin thereby increasing the mechanical strength of the printed circuit board 100. The substrate for use with the present invention may further comprise through-holes with conductive material provided therein for making electrical connection between different layers of conductor circuits in the substrate. Furthermore, the substrate for use with the present invention preferably has a solder resist (not shown) formed thereon and the solder resist has openings formed corresponding to the contacts or pads such as the contacts 110a, 110b, 110c or the pads 120b such that the contacts or pads are exposed from the solder resist.

Then, solder balls 130 are mounted on the interconnection pads 120b of the substrate 120 or the second set of contacts 110b of the substrate 110. Specifically, it is accomplished by the following steps of: (a) loading solder balls 130 into a fixture drilled with holes in a pattern matching the desired solder ball array; (b) printing eutectic solder paste onto the interconnection pads 120b or the second set of contacts 110b; (c) transferring the solder balls on the fixture to the solder paste on pads by a vacuum suction head; and (d) reflowing in a profile that melts only the eutectic solder.

Next, the substrate 120 is placed on the upper surface of the substrate 110 in a manner that the first set of contacts 110a are exposed through the opening 120a and the interconnection pads 120b of the substrate 120 are aligned with the second set of contacts 110b of the substrate 110. At this time, the solder balls already on a substrate are aligned to corresponding pads or contacts on another substrate wherein solder paste has been be screened on the pads or contacts.

After that, in another reflow operation, the solder paste is melt to form a solder bond between the corresponding pads or contacts on the substrates 110, 120.

Referring to FIG. 2, the method of making a multilayer printed circuit board 200 according to a second preferred embodiment of the present invention is set forth below. The method is characterized in that the substrate 120 is mechanically and electrically attached to the substrate 110 via column-like solder bumps 150. Preferably, the column-like solder bumps 150 are formed on the interconnection pads 120b of the substrate 120 or the second set of contacts 110b of the substrate 110 by stencil printing. Then, a reflow operation is conducted to melt the solder bumps 150 to form a solder bond between the corresponding pads or contacts on the substrates 110, 120, thereby mechanically and electrically attaching the substrate 120 onto the substrate 110.

In the first and the second preferred embodiments of the present invention, preferably, an underfill 140 is formed between the substrate 110 and the substrate 120. Specifically, underfill material is laid down along the edge of the gap between the substrate 110 and the substrate 120 by using an automated underfill dispense system. Then, the underfill material is pulled in the gap by capillary action. At that, the product of underfilling is placed into an underfill curing oven, and then the underfill is cured.

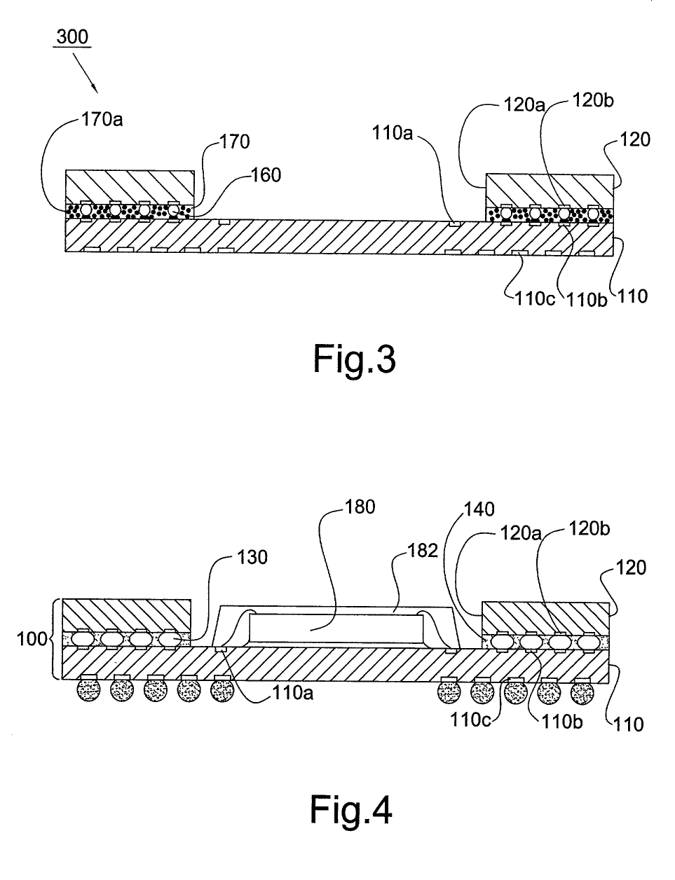

Referring to FIG. 3, the method of making a multilayer printed circuit board 300 according to a third preferred embodiment of the present invention is set forth below.

First, a plurality of metal bumps 160 are formed on the interconnection pads 120b of the substrate 120. Alternatively, the metal bumps 160 may be formed on the second set of contacts 110b of the substrate 110. Preferably, the metal bumps 160 are stud bumps formed from conventional wire bonding techniques. Alternatively, the metal bumps 160 may be formed by a conventional bumping technology comprising the steps of: (a) forming an under bump metallurgy (UBM) on the contacts or pads of the substrate by, e.g., electroless nickel/gold plating, and (b) forming metal bumps on the UBM by, e.g., vapor deposition, electroplating or printing.

Next, the substrate 120 is placed onto the upper surface of the substrate 110 with an anisotropic conductive adhesive film (ACF) 170 interposed therebetween in a manner that the first set of contacts 110a are exposed through the opening and the interconnection pads 120b of the substrate 120 are aligned with the second set of contacts 110b of the substrate 110. One type of anisotropic adhesive suitable for forming the ACF 170 is known as a “z-axis anisotropic adhesive”. Z-axis anisotropic adhesives are filled with conductive particles 170a to a low level such that the particles do not contact each other in the xy plane. Therefore, compression of the material in the z direction establishes an electrical path.

Then, after conducting a thermocompression bonding, the substrate 120 is adhered to the substrate 110 through the ACF 170, and the metal bumps 160 on the interconnection pads 120b of the substrate 120 are electrically coupled to corresponding contacts 110b. It could be understood that the ACF may be thermosetting or thermoplastic. Thermal plastic anisotropic adhesives are heated to soften for use and then cooled for curing. Thermal setting anisotropic adhesives require heat curing at temperatures from 100° C.-300° C. for from several minutes to an hour or more.

In the method of making printed circuit board according to the present invention, the substrates 110, 120 are manufactured and tested separately before mounting together. It is noted that electrical connection between the substrates 110, 120 is not achieved by conventional through-holes, instead, the substrates 110, 120 are mechanically and electrically interconnected to each other via solder balls, column-like solder bumps or ACF. Therefore, pattern density of the first substrate and the second substrate are not limited by the through-holes, and more circuits can be designed in the substrate thereby overcoming, or at least reducing the above-mentioned problems of the prior art.

FIG. 4 shows a semiconductor chip package using the multilayer printed circuit board 100 according to the present invention. The package mainly comprises a chip 180 mounted on the printed circuit board 100. The chip 180 is mounted inside the cavity of the printed circuit board 100 by a die attach material, and then, bond wires, for example, gold wires, are bonded by wire bonding machines (not shown) to connect bonding pads on the chip 180 to the first set of contact 110a. Thereafter, the chip 180 is sealed in a package body 182 by a conventional transfer-molding process. Alternatively, the package body may be formed by a glob-top process. Although only the printed circuit board 100 is illustrated as preferred embodiments in the semiconductor chip package shown in FIG. 4, a semiconductor chip package using the printed circuit board 200 or 300 is still considered within the spirit and scope of the invention.

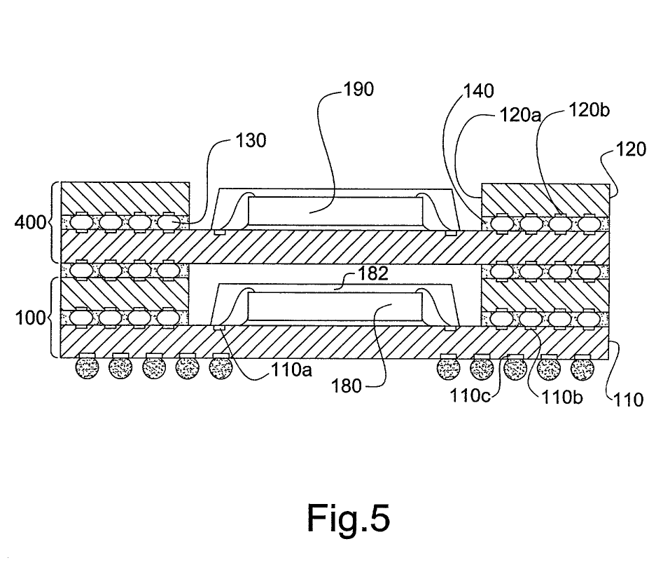

FIG. 5 shows a multichip module using multilayer printed circuit board 100 according to the present invention. The module is characterized by further comprising a chip 190 mounted inside the cavity of a multilayer printed circuit board 400 mechanically and electrically attached to the multilayer printed circuit board 100 via solder balls. It should be understood that the multilayer printed circuit board 400 may be mechanically and electrically attached to the multilayer printed circuit board 100 via column-like solder bumps or anisotropic conductive adhesive film (ACF). Preferably, the chips 180, 190 may be are packaged and tested separately before mounting the multilayer printed circuit board 400 to the multilayer printed circuit board 100.

The semiconductor chip packages according to the present invention can be mounted onto an outside substrate, such as a printed circuit board (PC board), via solder balls. Alternatively, the pads on the bottom surface of the packages can be printed with solder paste and then mounted onto the outside substrate.

Although the invention has been explained in relation to its preferred embodiment, it is to be understood that many other possible modifications and variations can be made without departing from the spirit and scope of the invention as hereinafter claimed.

What is claimed is:

1. A method of making a printed circuit board comprising:
providing a first substrate having opposing upper and lower surfaces, the upper surface of the first substrate being provided with a first set of contacts adapted for electrical coupling to a semiconductor chip and a second set of contacts, the lower surface of the first substrate being provided with a third set of contacts electrically interconnected to the first set of contacts and the second set of contacts;
providing a second substrate having an opening defined therein and a set of interconnection pads formed on a lower surface thereof;
mounting a plurality of solder balls on the interconnection pads of the second substrate or the second set of contacts of the first substrate;
placing the second substrate on the upper surface of the first substrate in a manner that the first set of contacts are exposed through the opening and the interconnection pads of the second substrate are aligned with the second set of contacts of the first substrate; and
reflowing so as to mechanically and electrically attach the second substrate to the first substrate through the solder balls.

2. The method as claimed in claim 1, wherein the third set of contacts are adapted for electrical coupling to an external printed circuit board.

3. The method as claimed in claim 1, further comprising the step of forming an underfill between the first substrate and the second substrate.

4. A method of making a printed circuit board comprising:
providing a first substrate having opposing upper and lower surfaces, the upper surface of the first substrate being provided with a first set of contacts adapted for electrical coupling to a semiconductor chip and a second set of contacts, the lower surface of the first substrate being provided with a third set of contacts electrically interconnected to the first set of contacts and the second set of contacts;
providing a second substrate having an opening defined therein and a set of interconnection pads formed on a lower surface thereof;
stencil printing a plurality of column-like solder bumps on the interconnection pads of the second substrate or the second set of contacts of the first substrate;
placing the second substrate on the upper surface of the first substrate in a manner that the first set of contacts are exposed through the opening and the interconnection pads of the second substrate are aligned with the second set of contacts of the first substrate; and
reflowing the solder bumps so as to mechanically and electrically attach the second substrate to the first substrate.

5. The method as claimed in claim 4, wherein the third set of contacts are adapted for electrical coupling to an external printed circuit board.

6. The method as claimed in claim 4, further comprising the step of forming an underfill between the first substrate and the second substrate.

7. A method of making a printed circuit board comprising:
providing a first substrate having opposing upper and lower surfaces, the upper surface of the first substrate being provided with a first set of contacts adapted for electrical coupling to a semiconductor chip and a second set of contacts, the lower surface of the first substrate being provided with a third set of contacts electrically interconnected to the first set of contacts and the second set of contacts;
providing a second substrate having an opening defined therein and a set of interconnection pads formed on a lower surface thereof;
forming a plurality of metal bumps on the interconnection pads of the second substrate or the second set of contacts of the first substrate;
placing the second substrate onto the upper surface of the first substrate with an anisotropic conductive adhesive film (ACF) interposed therebetween in a manner that the first set of contacts are exposed through the opening and the interconnection pads of the second substrate are aligned with the second set of contacts of the first substrate; and
conducting a thermocompression bonding so as to mechanically and electrically attach the second substrate to the first substrate through the ACF.

8. The method as claimed in claim 7, wherein the third set of contacts are adapted for electrical coupling to an external printed circuit board.

9. The method as claimed in claim 7, wherein the metal bumps are stud bumps formed from conventional wire bonding techniques.
